(19) United States
(12) Patent Application Publication
(10) Pub. No.: US 2021/0109034 A1
(43) Pub. Date: Apr. 15, 2021

(54) METHOD FOR DETECTING DEFECTS IN DEEP FEATURES

(71) Applicant: Yangtze Memory Technologies Co., Ltd., Wuhan City (CN)

(72) Inventors: SHENG CHAO NIE, Wuhan City (CN); JIN XING CHEN, Wuhan City (CN); SHI FENG CHENG, Wuhan City (CN)

(21) Appl. No.: 16/726,257

(22) Filed: Dec. 24, 2019

Related U.S. Application Data
(63) Continuation of application No. PCT/CN2019/110774, filed on Oct. 12, 2019.

(51) Int. Cl. G01N 21/95; G01N 21/88

(52) U.S. Cl. CPC G01N 21/9501; G01N 21/8806

(57) ABSTRACT

A method for detecting defects in high-aspect-ratio channel holes, via holes or trenches is disclosed. First, a substrate having thereon a film stack and a plurality of deep features in the film stack is provided. At least one of the plurality of deep features comprises a defect. The substrate is then subjected to an optical inspection process. The substrate is illuminated by a broadband light beam. Some of the broadband DUV light beam scattered and/or reflected from the substrate is collected by a detector, thereby producing a bright-field illumination image of the plurality of deep features in the film stack.

### CROSS REFERENCE TO RELATED APPLICATIONS

The present patent application is a continuation of PCT application Ser. No. PCT/CN2019/110774, filed Oct. 12, 2019, designating the United States, which is hereby incorporated by reference.

### BACKGROUND OF THE INVENTION

### 1. Field of the Invention

The present disclosure relates to a defect inspection method. More particularly, the present disclosure relates to a non-destructive method for capturing defects at the bottom of deep (high-aspect-ratio) features, such as holes, vias, slits and/or trenches.

### 2. Description of the Prior Art

Three-dimensional (3D) NAND memory continues to advance, as the stack gets thicker, cell density gets higher and the critical dimension (CD) continues to shrink. In the process of 3D NAND memory manufacturing, with the increase of the number of layers of film stack and the emergence of multi-stack technology, the detection of defects at the lower-stack, esp. for deep (high-aspect-ratio) features like holes, vias, slits and/or trenches, has become more and more critical.

However, due to the high aspect ratio (40˜100) of the channel hole, the conventional method of detecting defects such as under-etch defects at the bottom of the channel hole is difficult to implement. The existing method mainly realizes the bottom defect detection by removing the surface film with acid wash to reveal the buried defects, followed by a high sensitivity defect inspection. The existing method is an expensive and destructive approach, which has low precision and high difficulty to meet the production demand.

Therefore, there is a strong need in industry to provide an effective method for rapidly and directly detecting defects at the bottom of deep features.

### SUMMARY OF THE INVENTION

It is one object of the present disclosure to provide an improved defect inspection method that is able to capture defects at the bottom of deep features like holes, vias, slits and/or trenches in a non-destructive, low-cost, easy-handling and in-line manner.

According to one aspect of the present disclosure, a method for detecting defects in deep (high-aspect-ratio) channel holes, via holes, slits and/or trenches is disclosed. First, a substrate having thereon a film stack and a plurality of deep features in the film stack is provided. At least one of a plurality of deep features comprises a defect. The substrate is then subjected to an optical inspection process. The substrate is illuminated by a broadband light beam. Some of the broadband DUV light beam scattered and/or reflected from the substrate is collected by a detector, thereby producing a bright-field illumination image of the plurality of deep features in the film stack.

According to some embodiments, the defect is an under-etch defect.

According to some embodiments, the under-etch defect is a residual polysilicon plug remained at a bottom of the at least one of the plurality of deep features.

According to some embodiments, the broadband light beam is a broadband deep ultraviolet (DUV) light beam.

According to some embodiments, the broadband deep ultraviolet (DUV) light beam has a wavelength ranging between 270 nm and 400 nm.

According to some embodiments, the substrate is illuminated by the broadband light beam at a focus ranging between −0.2 and −1.2.

According to some embodiments, the substrate is a semiconductor substrate.

According to some embodiments, the film stack is an alternating oxide/nitride film stack.

According to some embodiments, each of the plurality of deep features has an aspect ratio ranging between 40 and 100.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings, which are incorporated herein and form a part of the specification, illustrate embodiments of the present disclosure and, together with the description, further serve to explain the principles of the present disclosure and to enable a person skilled in the pertinent art to make and use the present disclosure.

FIG. 1 is a schematic cross-sectional diagram showing a germane portion of an exemplary 3D NAND memory device in accordance with one embodiment of the present disclosure; and

FIG. 2 is a schematic diagram of an exemplary wafer inspection system according to one embodiment of the present disclosure.

Embodiments of the present disclosure will be described with reference to the accompanying drawings.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It is noted that references in the specification to “one embodiment,” “an embodiment,” “an exemplary embodiment,” “some embodiments,” etc., indicate that the embodiment described may include particular features, structures, or characteristics, but every embodiment may not necessarily include the particular features, structures, or characteristics. Moreover, such phrases do not necessarily refer to the same embodiment.

Further, when a particular feature, structure or characteristic is described in contact with an embodiment, it would be within the knowledge of a person skilled in the pertinent art to affect such feature, structure or characteristic in contact with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90° or at other orientations) and the spatially relative descriptors used herein may likewise be interpreted accordingly. The term “vertical” refers to the direction perpendicular to the surface of a semiconductor substrate, and the term “horizontal” refers to any direction that is parallel to the surface of that semiconductor substrate.

Wafer inspection using either optical or electron beam imaging are important techniques for debugging semiconductor manufacturing processes, monitoring process variations, and improving production yield in the semiconductor industry. With the ever decreasing scale of modern integrated circuits (ICs) as well as the increasing complexity of the manufacturing process, inspection becomes more and more difficult. As previously mentioned, current inspection approach to address buried defects in high aspect ratio (HAR) holes or deep holes is utilizing a destructive etch-back of the wafer to expose process issues such as under-etch defects, followed by a high sensitivity defect inspection. Non-destructive, fast measurements of the full HAR profile such as the channel hole are currently not available.

The present disclosure pertains to a method for detecting defects in deep (high-aspect-ratio) features like channel holes, via holes, slits or trenches. First, a substrate having thereon a film stack and a plurality of deep features in the film stack is provided. At least one of the plurality of deep features comprises an under-etch defect such as a residual polysilicon plug remained at the bottom of at least one of the plurality of deep features. The substrate is then subjected to an optical inspection process. The substrate is illuminated by a broadband deep ultraviolet (DUV) light beam. Some of the broadband DUV light beam scattered and/or reflected from the substrate is collected by a detector, thereby producing a bright-field illumination image of the plurality of deep features in the film stack.

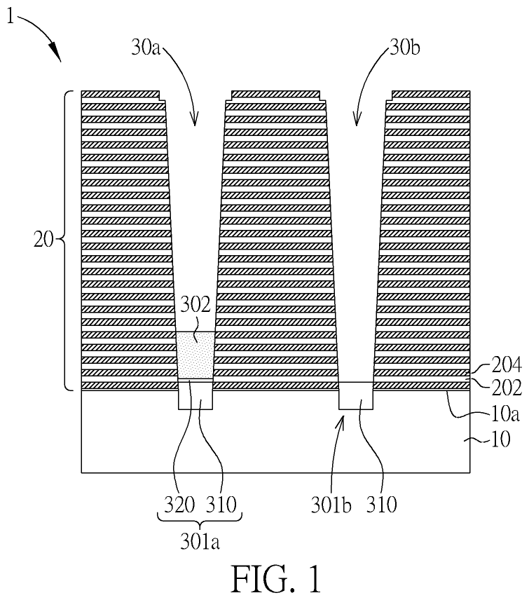

FIG. 1 is a schematic, cross-sectional diagram showing a germane portion of an exemplary 3D NAND memory device in accordance with one embodiment of the present disclosure. As shown in FIG. 1, a substrate 10 is provided. The substrate 10 may be a semiconductor substrate. According to one embodiment, for example, the substrate 10 may comprise a silicon substrate. According to some embodiments, for example, the substrate 10 may comprise a silicon-on-insulator (SOI) substrate, a SiGe substrate, a SiC substrate, or an epitaxial substrate, but it's not limited thereto. A film stack 20 for the fabrication of a three-dimensional (3D) memory cell array such as a 3D NAND flash memory array may be formed on the substrate 10.

For example, the film stack 20 may have a thickness of about 4˜8 μm, but it's not limited thereto. For example, the film stack 20 may be an alternating oxide/nitride film stack comprising multiple layers of alternating oxide layer 202 and nitride layer 204. According to one embodiment, for example, the nitride layers 204 may be sacrificial silicon nitride layers and may be selectively removed in the later stage. After the nitride layers 204 are selectively removed, conductor layers, which may function as word line strips or gate electrodes, may be deposited in place of the nitride layers 204.

It is to be understood that the substrate 10 may include integrated circuits fabricated thereon, such as driver circuits for the 3D memory cell array, which are not shown in the figures for the sake of simplicity. The alternating oxide layer 202 and nitride layer 204 may be formed by chemical vapor deposition (CVD) methods, atomic layer deposition (ALD) methods, or any suitable methods known in the art.

According to one embodiment, for example, multiple deep features such as channel holes are formed in the film stack 20. For example, each of the plurality of deep features has an aspect ratio ranging between 40 and 100. For the sake of simplicity, only two exemplary channel holes 30a and 30b are shown in the figures. It is to be understood that an array of channel holes may be formed in the film stack 20. According to one embodiment, for example, the channel holes 30a and 30b are hollow, cylindrical deep holes penetrating through the film stack 20. According to one embodiment, for example, the channel holes 30a and 30b may be formed by using anisotropic dry etching methods such as reactive ion etching (RIE) methods, but not limited thereto.

According to one embodiment, for example, the channel hole 30a may comprise at least one end portion 301a, which extends substantially perpendicular to a major surface 10a of the substrate 10. The end portion 301 may comprise an epitaxial silicon layer 310 and a sacrificial protection layer 320 capping the epitaxial silicon layer 310. For example, the sacrificial protection layer 320 may be a thin silicon oxide layer having a thickness ranging between 5 angstroms and 100 angstroms. For example, the sacrificial protection layer 320 may have a thickness of about 45 angstroms.

According to one embodiment, for example, the channel hole 30a further comprises an under-etch defect 302. According to one embodiment, for example, the under-etch defect 302 is a residual polysilicon layer or polysilicon plug remained in the channel hole 30a. According to one embodiment, for example, the under-etch defect 302 is disposed on the sacrificial protection layer 320. According to one embodiment, for example, the channel hole 30b comprises an end portion 301b consisting of the epitaxial silicon layer 310. As can be seen in this figure, the polysilicon layer and the sacrificial protection layer are completely removed from the channel hole 30b and a top surface of the epitaxial silicon layer 310 is exposed from the bottom of the channel hole 30b. Therefore, the exemplary channel hole 30a represents an abnormal channel hole, while the exemplary channel hole 30b represents a normal channel hole.

As previously mentioned, to capture the under-etch defect 302 in the abnormal channel hole 30a, it is the conventional method to etch away the film stack 20 using acid wash to expose the under-etch defect 302, followed by a high sensitivity defect inspection. However, the conventional method is expensive and destructive, and is low in precision. The conventional method is difficult to meet the production demand. The present disclosure addresses this issue by providing a non-destructive, precise, and efficient inspection method to capture the under-etch defect 302 in the HAR channel hole 30a.

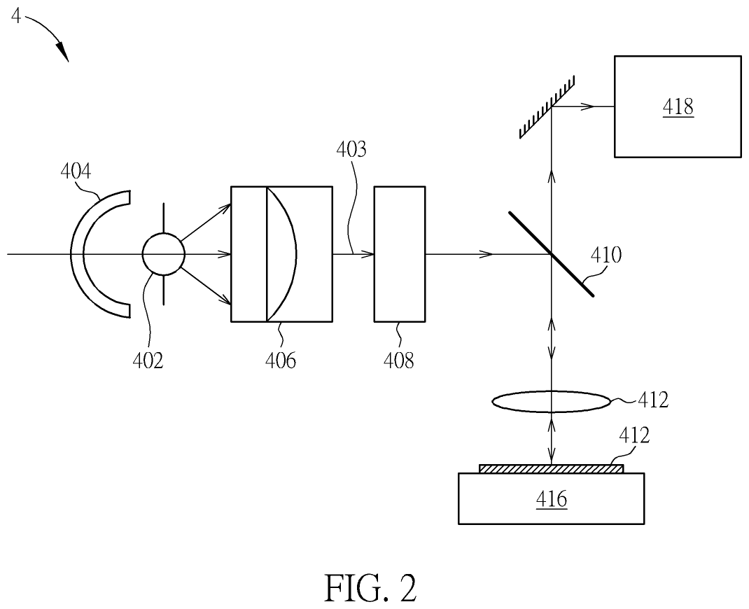

FIG. 2 is a schematic diagram of an exemplary wafer inspection system according to one embodiment of the present disclosure. As shown in FIG. 2, for example, the exemplary wafer inspection system 4 may use a broadband gas discharge light source 402. For example, the broadband gas discharge light source 402 may use hydrogen and/or deuterium in the discharge gas. By way of example and without limitation, the discharge lamp 402 may include an enclosure having one or more walls, at least one of which is at least partly transparent. A gas mixture including, but not limited to, hydrogen and/or deuterium may be contained within the enclosure. A curved mirror 404 and condenser lens 406 focuses and collimate broadband light from the discharge source 402. The broadband light 403 such as broadband deep ultraviolet (DUV) passes through a filter 408 and is reflected off a beam splitter 410 and focused by an objective lens 412 onto the surface of a sample under inspection 414 that is secured on a stage 516. According to one embodiment, the incident broadband light 403 impinges on the surface of the sample under inspection 414 in a substantially perpendicular manner. According to one embodiment, the sample under inspection 414 comprises the HAR hole structure as depicted in FIG. 1. According to one embodiment, some of the radiation scattered and/or reflected from the surface of the sample under inspection 414 passes back through the beam splitter 410 and is collected by a detector 418, thereby producing a bright-field illumination image.

The present disclosure takes advantage of the penetration characteristics of light to realize the detection of defects in or at the bottom of deep features. Compared to electron beams, the wavelength of light is larger enough to penetrate through deeper in the film stack 20. By adjusting the position of the sample wafer or substrate under inspection so that the focal point of the incident light 403 is in the interior of the film stack 20 close to the substrate 10, the optical anomaly caused by the defect 302 can be observed and distinguished, and the defect 302 can be detected by comparison with a normal optical image. By adjusting the wavelength of the incident light 403, the requirements of depth of detection and image sharpness can be balanced, and the rapid and accurate detection of deep hole defects can be realized.

According to one embodiment, for example, the broadband light 403 is broadband DUV light and may have a wavelength ranging between 270 nm and 400 nm, but is not limited thereto. According to one embodiment, for example, the substrate is illuminated by the broadband light beam at a focus ranging between −0.2 and −1.2. For example, the focus may range between −0.5 and −0.9. For example, the focus may be −0.7. It is to be understood that the focus may be adjusted depending upon the distance between the objective lens 412 and the sample under inspection 414, the materials of the film stack 20 and the defect, and the thickness of film stack 20.

The disclosed defect inspection method enables accurate detection of deep feature defects without damaging the wafer or sample under inspection. The benefits of the present disclosure include high accuracy, no damage to the sample under inspection, and low cost.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A defect inspection method, comprising:
providing a substrate having thereon a film stack and a plurality of deep features in the film stack, wherein at least one of the plurality of deep features comprises a defect; and
subjecting the substrate to an optical inspection process, wherein the substrate is illuminated by a broadband light beam, and wherein some of the broadband DUV light beam scattered and/or reflected from the substrate is collected by a detector, thereby producing a bright-field illumination image of the plurality of deep features in the film stack.

2. The defect inspection method according to claim 1, wherein the defect is an under-etch defect.

3. The defect inspection method according to claim 2, wherein the under-etch defect is a residual polysilicon plug remained at a bottom of the at least one of the plurality of deep features.

4. The defect inspection method according to claim 1, wherein the broadband light beam is a broadband deep ultraviolet (DUV) light beam.

5. The defect inspection method according to claim 4, wherein the broadband deep ultraviolet (DUV) light beam has a wavelength ranging between 270 nm and 400 nm.

6. The defect inspection method according to claim 1, wherein the substrate is illuminated by the broadband light beam at a focus ranging between −0.2 and −1.2.

7. The defect inspection method according to claim 1, wherein the substrate is a semiconductor substrate.

8. The defect inspection method according to claim 1, wherein the film stack is an alternating oxide/nitride film stack.

9. The defect inspection method according to claim 1, wherein each of the plurality of deep features has an aspect ratio ranging between 40 and 100.
